(19) United States
(12) Patent Application Publication
(10) Pub. No.: US 2020/0168275 A1
(43) Pub. Date: May 28, 2020

(54) WRITING APPARATUS AND METHOD FOR COMPLEMENTARY RESISTIVE SWITCH

(71) Applicant: NEC Corporation, Minato-ku, Tokyo (JP)

(72) Inventors: Xu BAI, Tokyo (JP); Toshitsugu SAKAMOTO, Tokyo (JP); Yukihide TSUJI, Tokyo (JP); Makoto MIYAMURA, Tokyo (JP); Ayuka TADA, Tokyo (JP); Ryusuke NEBASHI, Tokyo (JP)

(73) Assignee: NEC Corporation, Minato-ku, Tokyo (JP)

(21) Appl. No.: 16/611,266

(22) PCT Filed: May 12, 2017
(86) PCT No.: PCT/JP2017/018043

§ 371 Date: Nov. 6, 2019

(51) Int. Cl. G11C 13/00; H03K 19/1776

(52) U.S. Cl. CPC G11C 13/0069; G11C 2013/0078; H03K 19/1776; G11C 13/004

(57) ABSTRACT

A reconfigurable circuit comprising: a complementary resistive switch; a write circuit to configure the complementary resistive switch; a read circuit to get ON/OFF information of the complementary resistive switch; a register to store ON/OFF information of the complementary resistive switch.

### TECHNICAL FIELD

The present invention relates to a reconfigurable circuit with non-volatile complementary resistive switches, and the method for using the reconfigurable circuit.

### BACKGROUND ART

A typical semiconductor integrated circuit (IC) is constructed by transistors build on a semiconductor substrate and upper layer wires used to connect the transistors. The patterns of transistors and wires are determined in a design stage of the IC. Interconnections between the transistors and wires cannot be changed after fabrication. In order to improve flexibility of IC, field-programmable gate arrays (FPGAs) have been proposed and developed. In FPGAs, configuration data including operation and interconnection information is stored in the memories, so that different logic operations and interconnections can be realized by configuring memories after fabrication according to requirements of end users. Interconnections within FPGA can be altered by controlling ON-and-OFF of switches in a routing multiplexer (MUX) or routing fabrics arranged in the FPGA in accordance with the interconnection information stored in the memories.

The relatively large energy consumption of FPGAs limits integration of commercial FPGAs into IoT (Internet of Things) devices. In most of commercial FPGAs, SRAM (Static Random Access Memory) is used to store the configuration data. Typically, each memory cell of SRAM is composed of six transistors and each modern FPGA chip has more than 10M (ten-million) memory cells of SRAM. This causes extremely large area overhead, cost, and energy consumption in FPGAs.

Recently, FPGAs with non-volatile resistive switches (NVRSs) such as Nanobridge(R) (NB) integrated between the wires upon a transistor layer have been proposed to overcome the problems of SRAM-based FPGAs and achieve small area overhead [NPL 1, NPL 2]. To achieve high off-state reliability, two NVRSs are serially connected with opposite direction and are configured via the programming transistor, where the device is named as complementary NVRS (CNVRS). An example of the CNVRS which can be applied to a memory portion of LSI (Large-Scale Integration) is disclosed in [PTL 2].

FIG. 1 illustrates a typical structure of the FPGA using the CNVRSs. A large number of cells constitute a cell array. Each cell consists of a routing MUX and a logic block. In this example, logic block includes two look-up tables (LUTs), two D-type flip-flops and two selectors. The routing MUX includes a plurality of input and output lines arranged in a lattice manner which are connected to logic block and adjacent cells. Data routing switch is arranged at each cross-point or intersection between the vertical lines and the horizontal lines. Therefore, routing MUX has a crossbar structure. In FIG. 1, enlarged view illustrates four CNVRSs which are arranged at cross-points between vertical lines L_{V0} and L_{V1} and horizontal lines L_{H0} and L_{H1}. If CNVRS S₀₀ is in the ON-state or set state, the vertical line L_{V0} is electrically connected to the horizontal line L_{H0}. A signal can be transmitted from the input IN0 to the output OUT0. On the other hand, if CNVRS S₀₀ is in the OFF-state or reset state, the vertical line L_{V0} is not electrically connected to the horizontal line L_{H0}. No signal can transmit from the input IN0 to the output OUT0.

### CITATION LIST

### Patent Literature

[PTL 1]: WO 2015/198573 A1
[PTL 2]: JP 2013-77681A
[PTL 3]: U.S. Pat. No. 7,486,111 B2

### Non Patent Literature

[NPL 1]: Munehiro Tada, et al., Improved OFF-State Reliability of Nonvolatile Resistive Switch with Low Programming Voltage, IEEE TRANSACTIONS ON ELECTRON DEVICES, Vol. 59, No. 9, pp. 2357-2362, SEPTEMBER 2012.
[NPL 2]: Makoto Miyamura, et al., Low-power programmable-logic cell arrays using nonvolatile complementary atom switch, ISQED 2014, pp. 330-334.

### SUMMARY OF INVENTION

### Technical Problem

In the CNVRS, two NVRSs have different set voltages due to process version, which results in write disturb problem. The exemplary object of the present invention is to provide a writing apparatus and a write method to solve the write disturb problem.

### Solution to Problem

A reconfigurable circuit comprising: a complementary resistive switch; a write circuit to configure the complementary resistive switch; a read circuit to get ON/OFF information of the complementary resistive switch; a register to store ON/OFF information of the complementary resistive switch.

### BRIEF DESCRIPTION OF DRAWINGS

FIG. 1 is a schematic view illustrating an exemplary structure of the FPGA using the CNVRSs.

FIG. 2 shows the NVRS and its write circuit according to a first exemplary embodiment of the present invention.

FIG. 3 illustrates a two-step write method according to a first exemplary embodiment of the present invention.

FIG. 4 illustrates a three-step write method according to a first exemplary embodiment of the present invention.

FIG. 5 illustrates structure of writing apparatus according to a first exemplary embodiment of the present invention.

FIG. 6 shows flow chart of writing apparatus according to a first exemplary embodiment of the present invention.

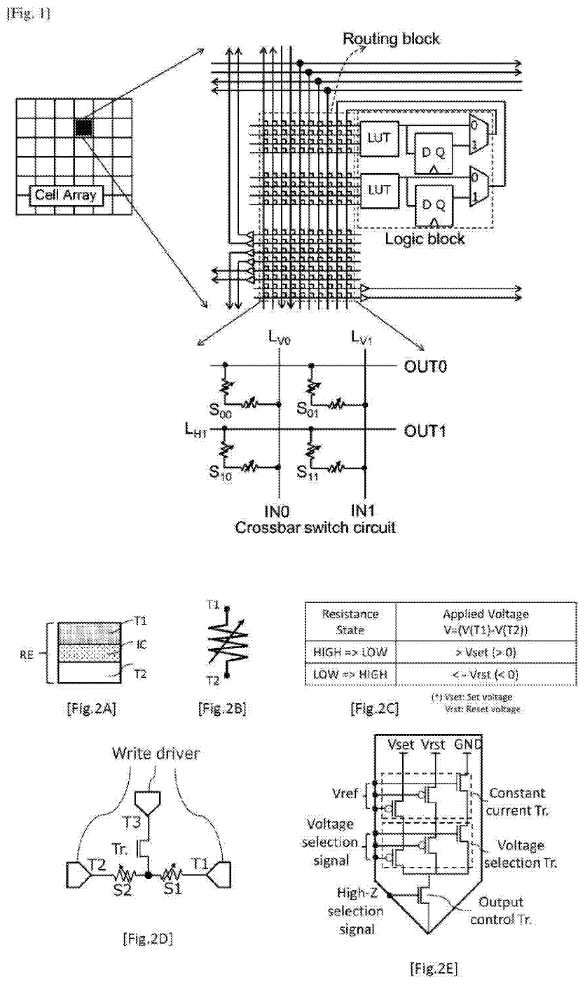

### DESCRIPTION OF EMBODIMENTS

Exemplary embodiment of the present invention will be next described with reference to the accompanying drawings.

### First Exemplary Embodiment

FIG. 2 illustrates the structure of the NVRS and its write circuit. As shown in FIG. 2 (a), The NVRS includes: active electrode T1 made of, for example, copper (Cu); inert electrode T2 made of, for example, ruthenium (Ru); and solid-electrolyte IC sandwiched between active electrode T1 and inert electrode T2. FIG. 2 (b) shows the symbolic of the NVRS. If a positive voltage (Vset) applied between T1 and T2, resistance of the NVRS becomes low, called ON state. On the other hand, if a negative voltage (Vrst) applied between T1 and T2, resistance of the NVRS becomes high, called OFF state (FIG. 2 (c)). The ratio of the high resistance and the low resistance is larger than 10⁵, so that the NVRS can be directly used as a switch for data routing. FIG. 2 (d) shows the CNVRS and its write circuit. Three write drivers and a programming transistor Tr. are used to configure the two NVRS. FIG. 2 (e) shows the write driver includes a set voltage (Vset), a reset voltage (Vrst) and a ground voltage (GND). Each of the above voltage line is serially connected to a constant current transistor, a voltage selection transistor and an output control transistor. A reference voltage Vref is applied to the constant current transistor to control current for each power voltage line. A voltage selection signal is applied to the voltage selection transistor to select one of the power voltage lines as an output. A high-Z selection signal is applied to the output control transistor to enable output of the write driver.

In the CNVRS, two NVRSs have different set voltages due to process version, which results in write disturb problem. We define weak switch has low set/reset voltage, while strong switch has high set/reset voltage. FIG. 3 illustrates a conventional two-step CNVRS write method. In the first step, to set NVRS S1, Vset is applied to terminal T1, GND is applied to terminal T3, and terminal T2 is set to Hi-Z. In the second step, to set NVRS S2, Vset is applied to terminal T2, GND is applied to terminal T3, and terminal T1 is set as Hi-Z. Disturb voltage is applied to S1. Disturb problem of S1 may happen. Or the ON state of S1 is not stable in harsh environment.

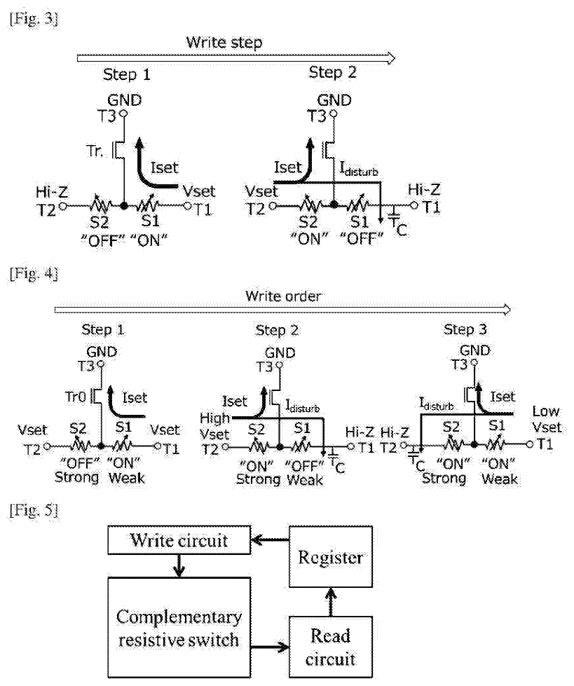

FIG. 4 illustrates a novel three-step write method with weak NVRS detection scheme. In the first step, to detect weak NVRS, Vset is applied to terminals T1 and T2, simultaneously, GND is applied to terminal T3. If S1 has lower set voltage than S2, S1 is set to ON state firstly. Then, the voltage of the common terminal of S1 and S2 becomes almost Vset, the voltage difference of two terminals of S2 becomes almost 0 V. S2 is kept as OFF state. Weak NVRS can be detected by reading ON/OFF state of S1 and S2. The ON-state NVRS is the weak one, while the OFF-state NVRS is the strong one. In the second step, to set strong NVRS S2 with high set voltage, a high Vset is applied to T2, GND is applied to T3 and T1 is set to Hi-Z. S1 may be disturbed as OFF state due to high Vset. In the third step, to set weak NVRS S1 with low set voltage, a low Vset is applied to T1, GND is applied to T3 and T2 is set to Hi-Z. Disturb problem will not happen in S2 because disturb voltage is smaller than reset voltage of strong NVRS S2. It is expected that fail rate of NVRS at high temperature can be reduced by at least 70%.

FIG. 5 shows a novel writing apparatus for the three-step write method. The write apparatus consists of a CNVRS, a write circuit, a read circuit and a register. The write circuit shown in FIG. 2 (d) is used to apply Vset, GND and Hi-Z to the CNVRS. A read circuit obtains ON/OFF state of the two NVRSs in the CNVRS in the first step. The register stores the ON/OFF in the first step.

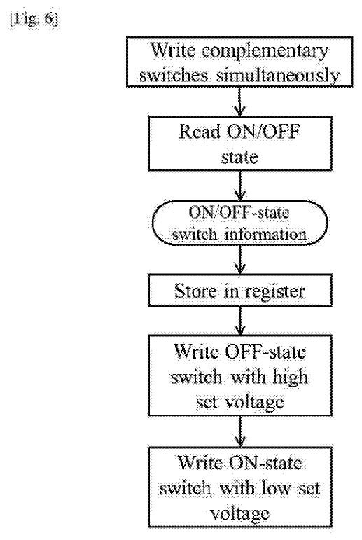

FIG. 6 illustrates flow chart of writing apparatus. At first, the write circuit is used to set two NVRSs in a CNVRS simultaneously, and the read circuit is used to get ON/OFF state information of the two NVRSs. Then, the ON/OFF state information is stored in the register. Finally, the write circuit is used again to write OFF-state switch with high Vset and ON-state switch with low Vset sequentially.

The reconfigurable circuits of the above exemplary embodiment may be used in, for example, mobile phone, IoT (Internet of Things) devices, and so on. A high reliable FPGA using the CNVRSs can be realized by the reconfigurable circuits described above.

It is apparent that the present invention is not limited to the above exemplary embodiments and examples, but may be modified and changed without departing from the scope and sprit of the invention.

What is claimed is:

1. A reconfigurable circuit comprising:
a complementary resistive switch with three terminals;
a write circuit to configure said complementary resistive switch;
a read circuit to get ON/OFF information of said complementary resistive switch; and
a register to store ON/OFF information of the said complementary resistive switch.

2. The reconfigurable circuit according to claim 1, wherein said complementary resistive switch includes two serially connected resistive switches and three terminals, wherein a first terminal of a first resistive switch is used as a first terminal of said complementary resistive switch, a first terminal of a second resistive switch is used as a second terminal of said complementary resistive switch, second terminals of said first and second resistive switches are connected with each other and used as a third terminal of said complementary resistive switch.

3. The reconfigurable circuit according to claim 1, wherein said write circuit provides set voltage, reset voltage, ground voltage and hi-Z to said complementary resistive switch.

4. The reconfigurable circuit according to claim 1, wherein said register stores ON/OFF information obtained by said read circuit.

5. The reconfigurable circuit according to claim 1, wherein said write circuit receives ON/OFF information stored in said register.

6. A write method for reconfigurable circuit comprising a complementary resistive switch which has three terminals, wherein a first terminal of a first resistive switch is used as a first terminal of said complementary resistive switch, a first terminal of a second resistive switch is used as a second terminal of said complementary resistive switch, second terminals of said first and second resistive switches are connected with each other and used as a third terminal of said complementary resistive switch; a write circuit to configure said complementary resistive switch; a read circuit to get ON/OFF information of said complementary resistive switch; a register to store ON/OFF information of the said complementary resistive switch, the method comprising:
applying set voltage from said write circuit to said first and second terminals of said complementary resistive switch simultaneously; and
applying ground voltage from said write circuit to said third terminal of said complementary resistive switch.

7. The write method according to claim 6, further comprising:
obtaining ON/OFF information of said complementary resistive switch by said read circuit.

8. The write method according to claim 7, further comprising:
storing ON/OFF information of said complementary resistive switch in said register.

9. The write method according to claim 8, further comprising:
writing OFF-state resistive switch and ON-state resistive switch sequentially.

10. The write method according to claim 8, further comprising:
writing OFF-state resistive switch using high set voltage and ON-state resistive switch using low set voltage.
